(19) United States
(12) Patent Application Publication
(10) Pub. No.: US 2009/0145350 A1
(43) Pub. Date: Jun. 11, 2009

(54) METHOD OF INJECTING DOPANT GAS

(75) Inventors: Yasuhito Narushima, Kanagawa (JP); Fukuo Ogawa, Kanagawa (JP); Shinichi Kawazoe, Kanagawa (JP); Toshimichi Kubota, Kanagawa (JP)

Correspondence Address: FRISHAUF, HOLTZ, GOODMAN & CHICK, PC, 220 Fifth Avenue, 16TH Floor, NEW YORK, NY, 10001-7708, US

(73) Assignee: SUMCO TECHXIV CORPORATION, Kanagawa (JP)

(21) Appl. No.: 12/088,386

(22) PCT Filed: Sep. 27, 2007
(86) PCT No.: PCT/JP2007/068763

§ 371 Date: Mar. 27, 2008

(30) Foreign Application Priority Data
Sep. 29, 2006 (JP) 2006-267777

(51) Int. Cl. C30B 9/00

(52) U.S. Cl. 117/77

(57) ABSTRACT

According to an dopant-injection method for injecting volatilized dopant gas into semiconductor melt in a crucible (31), the crucible (31) is rotated alternately clockwise and counterclockwise around a support shaft (36) extending in a flowing direction of the dopant gas, so that the dopant gas is blown against the semiconductor melt white the crucible is rotated. Rotating the crucible (31) causes convection currents in the semiconductor melt therein, thereby facilitating diffusion of the blown dopant in the semiconductor melt.

### TECHNICAL FIELD

The present invention relates to a dopant-injecting method for injecting volatilized dopant gas into semiconductor melt in a crucible.

### BACKGROUND ART

In order to adjust resistance value of semiconductor wafers, dopant such as phosphorus or arsenic has been conventionally doped therewith before pulling up ingots during a growing process of silicon monocrystal. Doping is conducted by injecting dopant into semiconductor melt in crucibles.

As the dopant, volatile dopant and nonvolatile dopant are known. When injecting volatile dopant such as arsenic or red phosphorus, the volatile dopant is accommodated in a doping device that includes a container whose lower end is provided with a conduit for guiding gas. The volatile dopant therein is gasified by moving the lower end of the container closer to a surface of the semiconductor melt, such that dopant gas is injected into the semiconductor melt through the conduit. In addition, according to a traditional technique, a lower end of the conduit may be soaked in the semiconductor melt when necessary, thereby letting less dopant gas escape to the outside (see, Patent Documents 1 and 2).

[Patent Document 1] JP-A-2001-253791

[Patent Document 2] JP-A-2004-137140

### DISCLOSURE OF THE INVENTION

### Problems to Be Solved by the Invention

However, although the dopant gas can be injected into the semiconductor melt by the methods of injecting volatile dopant according to Patent Documents 1 and 2, the speed at which the dopant diffuses all over the semiconductor melt is so slow that a dopant-gas layer of high concentration is formed on the surface of the semiconductor melt against which the dopant gas is blown from the conduit.

Accordingly, by the time when pulling-up of ingots is started with a doping device being detached, the dopant in the layer of high concentration has been gasified from adjacent ingot surfaces, thereby preventing the dopant from sufficiently diffusing in the semiconductor melt.

An object of the present invention is to provide a method of injecting dopant by which dopant gas can sufficiently diffuse in semiconductor melt when doping the semiconductor melt with volatile dopant.

### Means for Solving the Problems

A dopant-injecting method according to an aspect of the present invention is a method for injecting volatilized dopant gas into semiconductor melt in a crucible, the method including:

rotating the crucible alternately clockwise and counterclockwise around an axis extending in a flowing direction of the dopant gas; and

blowing the dopant gas against the semiconductor melt while rotating the crucible.

According to this aspect, accommodated in a doping device that includes a container whose lower end is provided with a conduit for guiding dopant gas, volatile dopant is gasified by heat from semiconductor melt when the doping device is moved closer to a surface of the semiconductor melt, so that the dopant gas is blown against the surface of the semiconductor melt.

The volatile dopant may be arsenic, red phosphorus and the like.

According to the aspect of the present invention, by rotating the crucible containing the semiconductor melt clockwise and counterclockwise alternately, suitable changes of convection currents are caused in the semiconductor melt in the crucible, thereby promoting the diffusion of the blown dopant gas. With this arrangement, the dopant having been injected from the surface of the melt can be prevented from being gasified, thereby enhancing dopant absorptivity.

Preferably in the method according to the aspect of the present invention, the dopant gas is supplied by volatile dopant accommodated in a doping device that comprises a container whose lower end is provided with a conduit for guiding the dopant gas to the semiconductor melt, and the dopant gas is blown against the semiconductor melt from a distal end of the conduit.

According to the aspect, the conduit of the doping device may or may not be soaked in the semiconductor melt so as to blow the dopant gas.

In an arrangement where the conduit is soaked in the semiconductor melt, the conduit of the doping device itself is preferably soaked therein when a single-tubular conduit is employed while only an outer tube of the conduit is preferably soaked therein when a double-tubular conduit is employed.

According to the aspect of the present invention, by blowing the doping gas against the semiconductor melt from a distal end of the conduit, the dopant gas blown against the surface of the semiconductor melt can be prevented from flowing out of the crucible due to its diffusion along the surface of the semiconductor melt, thereby promoting the injection of the dopant gas into the semiconductor melt. Since the doping device is made of quartz, it is preferable not to rotate the doping device in view of a risk of damages thereto.

Preferably in the method according to the aspect of the present invention, a change rate of a rotary speed (rotation number) of the crucible per unit time is in a range of 1 rpm/min to 10 rpm/min.

When the change rate is below 1 rpm/min, the rotary speed is so slow that the convection currents cannot be sufficiently changed in the semiconductor melt by alternately rotating the crucible.

On the other hand, when the change rate exceeds 10 rpm/min, the change of the rotary speed is so large that the semiconductor melt cannot follow the change and the convection currents cannot be sufficiently caused in the semiconductor melt.

Accordingly, by setting the change rate in a range of 1 rpm/min to 10 rpm/min, the convection currents can be sufficiently caused in the semiconductor melt in the crucible, thereby contributing to sufficient diffusion of the injected dopant gas in the semiconductor melt.

An upper limit of the rotary speed of the crucible is preferably in a range of −20 rpm to 20 rpm, provided that a clockwise direction is defined as positive while a counterclockwise direction is defined as negative.

### BRIEF DESCRIPTION OF DRAWINGS

FIG. 1 is an exemplary cross-sectional view showing an arrangement of a pulling-up device according to an embodiment of the present invention.

FIG. 2 is an exemplary cross-sectional view showing an arrangement of a doping device according to the embodiment.

FIG. 3 is an exemplary cross-sectional view showing a pulling-up device according to a modification of the embodiment.

FIG. 4 is a graph contrasting effects of examples and comparatives according to the present invention.

FIG. 5 is a graph contrasting effects of examples and comparatives according to the present invention.

### EXPLANATION OF CODES

1 . . . pulling-up device, 2 . . . doping device, 3 . . . device body, 21 . . . outer tube, 22 . . . inner tube, 23 . . . heat shielding member, 24 . . . support, 30 . . . chamber, 31 . . . crucible, 32 . . . heater, 33 . . . pulling-up portion, 34 . . . shield, 35 . . . heat insulating cylinder, 36 . . . support shaft, 211 . . . upper portion, 212A . . . support, 212 . . . lateral portion, 212B . . . projection, 221 . . . accommodating portion, 221A . . . upper portion, 221B . . . bottom portion, 221B1 . . . drop preventing wall, 221C . . . lateral portion, 221C1 . . . support piece, 222 . . . cylindrical portion, 222A . . . first cylindrical portion, 222A1 . . . groove, 222B . . . second cylindrical portion, 231 . . . heat shielding plate, 231A . . . heat shielding plate, 231A1 . . . heat shielding plate, 231A2 . . . heat shielding plate, 231B . . . heat shielding plate, 231B1 . . . heat shielding plate, 231B2 . . . heat shielding plate, 231B3 . . . heat shielding plate, 311 . . . first crucible, 312 . . . second crucible, 2311 . . . hole

### BEST MODE FOR CARRYING OUT THE INVENTION

An embodiment according to the present invention will be described below with reference to the attached drawings.

### [1] Overall Arrangement of Pulling-up Device 1

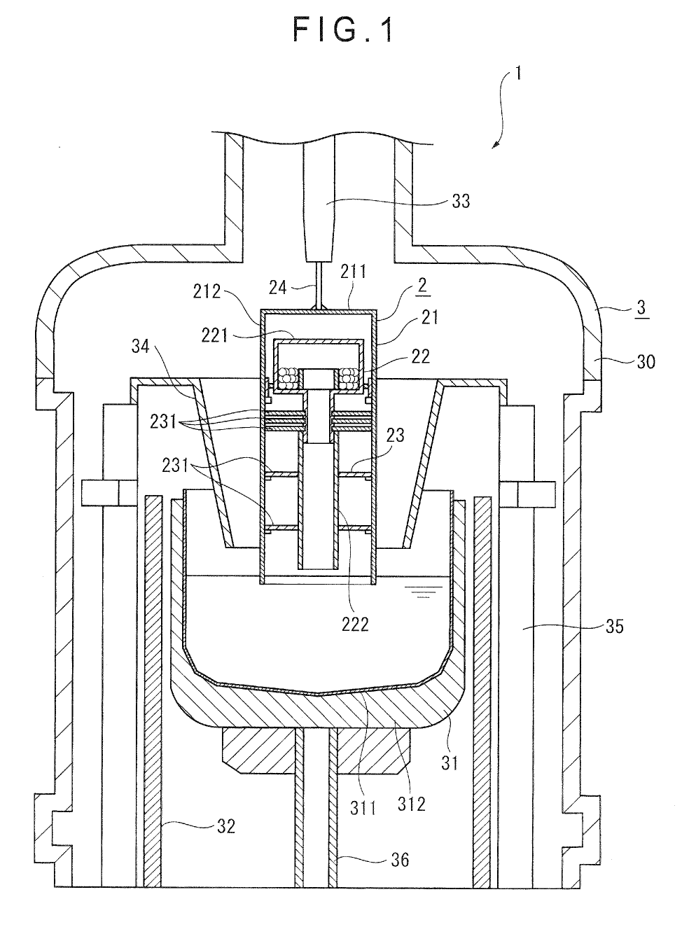

A pulling-up device 1 according to the present embodiment, which is shown in FIG. 1, includes a pulling-up device body 3 and a doping device 2.

The pulling-up device body 3 includes a chamber 30, a crucible 31 disposed inside the chamber 30, a heater 32 for heating the crucible 31 by heat radiation, a pulling-up portion 33, a shield 34 and a heat insulating cylinder 35.

Inert gas such as argon gas is injected into the chamber 30 from above to below. A pressure applied in the chamber 30, which is controllable, is generally set to be 5332 Pa or more and 79980 Pa or less in order to perform doping.

The crucible 31, which melts polycrystalline silicon (a material for a semiconductor wafer) into silicon melt, includes a bottomed-cylindrical first crucible 311 made of quartz and a graphite second crucible 312 disposed outside of the first crucible 311 for accommodating the first crucible 311.

The crucible 31, which is supported by a support shaft 36 that is rotatable around its center axis and elevatable, is rotated in accordance with rotating of the support shaft 36.

A rotary speed (rotation number) of the crucible 31 is settable within a range of −20 rpm to 20 rpm, provided that a clockwise rotation is defined as positive while a counterclockwise rotation is defined as negative in a top view of the crucible 31. A change rate of the rotary speed per unit time can be continuously changed from 0 rpm/min to 10 rpm/min.

The heater 32, which is disposed outside of the crucible 31, heats the crucible 31 so as to melt the silicon therein.

The pulling-up portion 33, which is disposed above the crucible 31, is mounted with a seed crystal or the doping device 2. The pulling-up portion 33 is rotatable and elevatable.

The heat insulating cylinder 35 is disposed so as to surround the crucible 31 and the heater 32.

The shield 34 is a heat-blocking shield for shielding radiant heat radiated from the heater 32 toward the doping device 2. The shield 34, which is disposed so as to surround the doping device 2 and cover a surface of the melt, is conical with its lower opening being smaller than its upper opening.

### [2] Arrangement of Doping Device 2

The doping device 2 is a device for volatilizing solid volatile dopant and doping the volatilized dopant on the silicon melt in the crucible 31.

The dopant may be, for instance, red phosphorus, arsenic and the like.

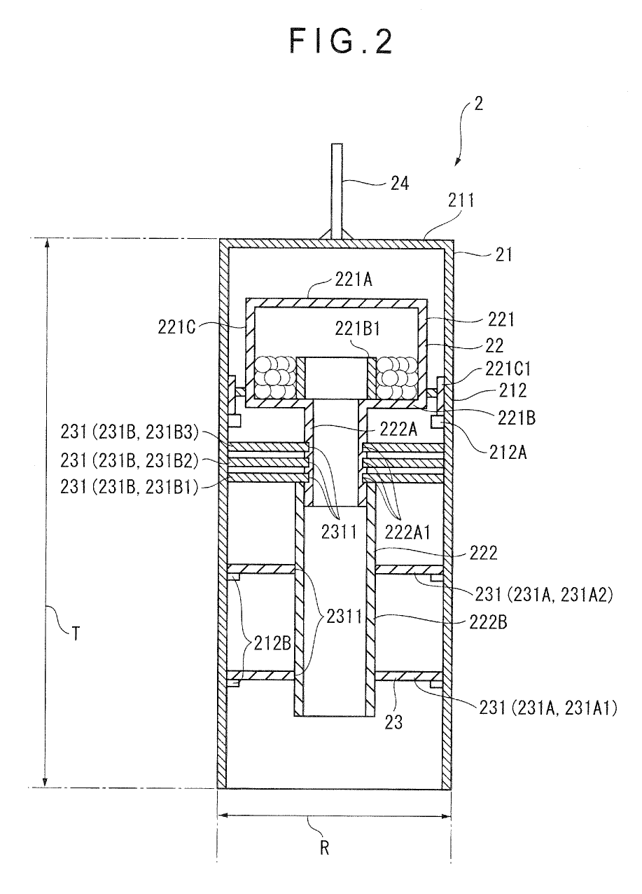

As shown in FIG. 2, the doping device 2 includes an outer tube 21, an inner tube 22 disposed inside the outer tube 21 and a heat shielding member 23.

The outer tube 21, which is bottomed-cylindrical with its lower end being opened while its upper end being closed, includes an upper portion 211 for providing an upper end surface and a lateral portion 212 that extends downwardly from an outer periphery of the upper portion 211. It should be noted that the lateral portion 212 of the outer tube 21 is cylindrical, and that an exemplary material for the outer tube 21 is transparent quartz.

A height dimension T of the outer tube 21 is exemplarily 450 mm, and a diameter R of the lateral portion 212 of the outer tube 21 is preferably in a range of 100 mm or more and 1.3 times or less of a diameter of a crystal to be pulled up.

The upper portion 211 of the outer tube 21 is provided with a support 24 that protrudes upwardly from the upper portion 211. By mounting the support 24 on the pulling-up portion 33 of the pulling-up device 1, the outer tube 21 is held by the pulling-up device (see FIG. 1).

The upper portion 211 of the outer tube 21 covers a later-described accommodating portion 221 of the inner tube 22 from the above. The upper surface 211 serves as a blow prevention member for preventing the above-mentioned inert gas that flows from top to bottom inside the chamber 30 (in other words, from top to bottom of the accommodating portion 221) from being directly blown against the accommodating portion 221.

The inner tube 22 includes the accommodating portion 221 and a cylindrical portion 222 connected to the accommodating portion 221 to communicate therewith. A material of the inner tube 22 may be, for example, transparent quartz.

The accommodating portion 221, which accommodates solid volatile dopant, is a hollow columnar portion.

The accommodating portion 221 includes a substantially plane-circular upper portion 221A, a bottom portion 221B disposed to face the upper portion 221A, a lateral portion 221C disposed between outer peripheries of the upper portion 221A and the bottom portion 221B.

The center of the bottom portion 221B is provided with an opening. Solid dopant is placed on the bottom portion 221B around the opening. When the solid volatile dopant is volatilized, the dopant gas is ejected through the opening. A circumference of the opening is provided with a drop preventing wall 221B1 for preventing the solid dopant from being dropped.

The dopant accommodated in the accommodating portion 221 is preferably positioned at a position where its temperature approaches the sublimation temperature of the dopant because, when the accommodating portion 221 is close to the melt, high temperature therefrom deteriorates thermal insulating effects. In this embodiment, the dopant is exemplarily placed approximately 300 mm away from the surface of the melt.

The lateral portion 221C is provided with a support piece(s) 221C1 that is substantially T-shaped in cross section, the support piece(s) protruding outwardly from the accommodating portion 221. By placing the support piece(s) 221C1 on a support(s) 212A formed on an inner circumference of the outer tube 21, the inner tube 22 is supported by the outer tube 21.

The cylindrical portion 222, which serves as a conduit for guiding the dopant gas volatilized in the accommodating portion 221 to the surface of the melt, is a columnar member with its upper and lower ends being opened. The upper end of the cylindrical portion 222 is connected to the opening of the bottom portion 221B of the accommodating portion 221.

A diameter of the cylindrical portion 222 is smaller than that of the outer tube 21, so that a gap is formed between an outer circumference of the cylindrical portion and an inner circumference of the outer tube 21.

In the present embodiment, the cylindrical portion 222 includes a first cylindrical portion 222A connected to the opening of the accommodating portion 221 and a second cylindrical portion 222B connected to the first cylindrical portion 222A to extend downwardly therefrom.

The first cylindrical portion 222A is integrally formed with the accommodating portion 221 while being separately formed from the second cylindrical portion 222B.

The first cylindrical portion 222A is provided with a plurality of ring-shaped grooves 222A1 formed along a circumferential direction of the first cylindrical portion 222A. In the present embodiment, three grooves 222A1 are formed. The grooves 222A1 serve to support later-described heat shielding plates 231 of the heat shielding member 23.

The second cylindrical portion 222B has a diameter in a range of 20 mm or more and 150 mm or less. Since the second cylindrical portion 222B in the present embodiment is a cylindrical member, its opening for ejecting the dopant gas also has a diameter in the range of 20 mm or more and 150 mm or less. When the outer tube 21 holds the inner tube 22, a lower distal end of the outer tube 21 protrudes further downward (toward the melt) than a lower distal end of the second cylindrical portion 222B.

The heat shielding member 23 serves to cover the accommodating portion 221 from the below and shields the radiant heat from the melt so that the volatile dopant is not unnecessarily volatized. The heat shielding member 23 has a plurality (exemplarily, five) of substantially plane-circular heat shielding plates 231.

Although the number of the heat shielding plates 231 may be suitably determined so as to correspond to a gas flow rate calculated based on a sublimation rate 10 to 50 g/min of the dopant gas blown against the melt, a flow rate of the gas flowing through the lower end of the cylindrical portion 222 is required to be larger than a flow rate of an evaporant evaporating from the melt.

The heat shielding plates 231 have outer diameters substantially equal to the inner diameter of the outer tube 21. The centers of the heat shielding plates 231 are provided with holes 2311 into which the cylindrical portion 222 is inserted. The heat shielding plates 231 are substantially horizontally disposed to shield the gap between the cylindrical portion 222 of the inner tube 22 and the outer tube 21 and to be substantially parallel to one another.

In the present embodiment, among the five heat shielding plates 231, heat shielding plates 231A disposed adjacently to the melt may be made of, for example, carbon insulation. The carbon insulation is formed by impregnating a material such as a thermoplastic resin with carbon fibers, curing the material by heating and burning the material under vacuum or under an atmosphere of inert gas.

For heat conductivity of the heat shielding plates 231A, a material whose heat conductivity is 20 W/m·° C. at 1412° C. may be exemplarily used.

Among the five heat shielding plates 231, three heat shielding plates 231B disposed adjacently to the accommodating portion 221 may be made of opaque quartz. Opaque quartz is formed by, for example, impregnating quartz glass with multiple fine bubbles.

For heat conductivity of the heat shielding plates 231B, a material whose heat conductivity is 8 W/m·° C. at 1412° C. may be exemplarily used.

The plurality of heat shielding plates 231 are disposed in the order of the two heat shielding plates 231A and the three heat shielding plates 231B from the lower end of the cylindrical portion 222.

The heat shielding plates 231A are supported by the outer tube 21 such that projections 212B formed on inner sides of the outer tube 21 supports the outer peripheries of the heat shielding plates 231A. A heat shielding plate 231A (231A1) that is the closest to the melt is disposed, for example, approximately 80 mm above the lower distal end of the cylindrical portion 222.

A heat shielding plate 231A2 above the heat shielding plate 231A1 is disposed, for example, approximately 170 mm above the lower distal end of the cylindrical portion 222. Hence, a gap of approximately 90 mm is formed between the heat shielding plate 231A1 and the heat shielding plate 231A2.

On the other hand, the heat shielding plates 231B are supported by the inner tube 22 such that the peripheries of the holes 2311 are supported by the grooves 222A1 of the first cylindrical portion 222A of the cylindrical portion 222 of the inner tube 22.

Among the three heat shielding plates 231B, a heat shielding plate 231B1 that is the closest to the melt is disposed, for example, approximately 250 mm above the lower distal end of the cylindrical portion 222.

A heat shielding plate 231B2 above the heat shielding plate 231B1 is disposed, for example, approximately 10 mm above the heat shielding plate 231B1.

In addition, a heat shielding plate 231B3 above the heat shielding plate 231B1 is disposed, for example, approximately 10 mm above the heat shielding plate 231B2. In other words, gaps of a predetermined size are formed between the heat shielding plates 231B.

The distance between the heat shielding plate 231B1 and the accommodating portion 221 is exemplarily 30 mm.

### [3] Injection of Dopant Using Pulling-up Device 1

When doping is conducted with the doping device 2 being mounted on the pulling-up device body 3, the support 24 provided on the outer tube 21 of the doping device 2 is mounted to the pulling-up portion 33 of the pulling-up device body 3, and an up-and-down position of the doping device 2 is adjusted such that a distal end of the lateral portion 212 of the outer tube 21 of the doping device 2 soaks in the melt as shown in FIG. 1.

In this state, the crucible 31 is rotated such that the change rate of the rotary speed (rotation number) is in a range of 1 rpm/min to 10 rpm/min while a maximum rotary speed is in a range of −20 rpm to 20 rpm. In other words, the crucible 31 is rotated around an axis extending along the flow of the dopant gas in the cylindrical portion 222 of the doping device 2.

Inert gas is subsequently flowed from an upper side of the pulling-up device 1 toward the melt. The inert gas flows along the surface of the melt.

The inert gas is continuously flowed during conducting the doping and pulling up a grown crystal. The flow rate of the inert gas is set to be in a range of 50 litters/min or more and 400 litters/min.

When the flow rate of the inert gas is set to exceed 400 litters/min, the accommodating portion 221 may be so excessively cooled that the dopant may not be volatilized or that the sublimated dopant may be solidified and adhered.

The dopant placed inside the accommodating portion 221 of the doping device 2 is gradually sublimated by the heat from the melt, such that the dopant in a gas form is ejected from the cylindrical portion 222 of the doping device 2 to be dissolved in the melt.

Convection currents, which are caused in the melt in the crucible 31 by the rotation of the crucible 31, facilitate diffusion of the injected dopant gas all over the melt.

A temperature of the melt in the crucible 31 at the time of doping is set to be in a range of a melt point of a material of the melt or more and the melt point plus 60° C. or less. In the present embodiment, since the material of the melt is silicon, the temperature of the melt is set to be in a range of 1412° C. or more and 1472° C. or less.

When the gas is dissolved in the melt, the pulling-up portion 33 of the pulling-up device 1 is detached from the doping device 2 and mounted with the seed crystal. Then, the pulling-up of the grown crystal is started.

### [4] Modification of Embodiments

The present invention is not limited to the above-described embodiments but may include modifications and improvements made within a scope where an object of the present invention can be achieved.

Although the distal end of the outer tube 21 (lateral portion 212) of the doping device 2 is soaked in the semiconductor melt for doping at the time of injecting the dopant using the doping device 2 in the above embodiments, the present invention is not limited thereto.

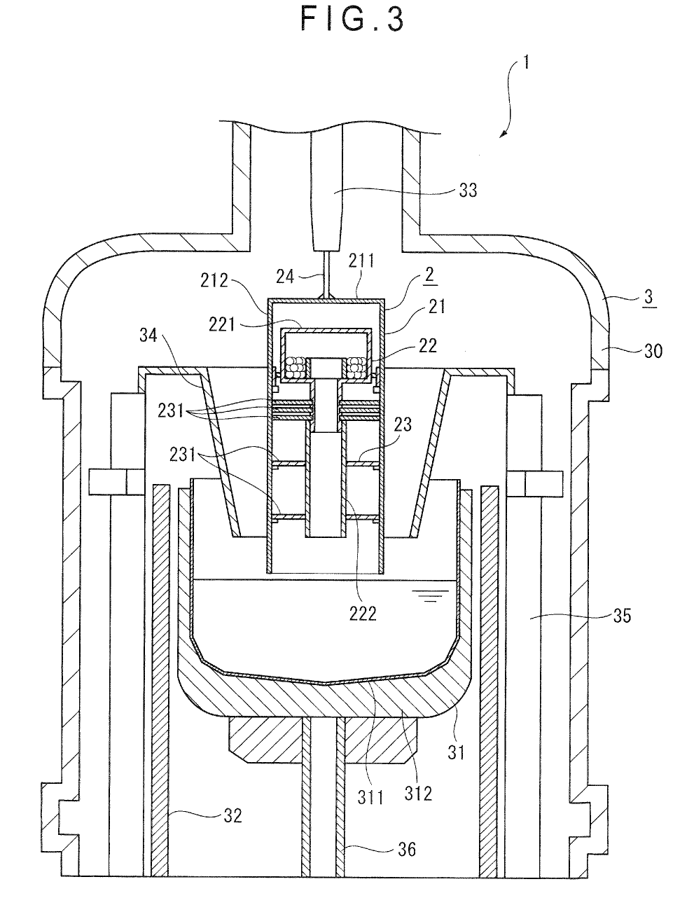

Specifically as shown in FIG. 3, the doping may be conducted with the outer tube 21 not being soaked in the semiconductor melt.

Although doping is conducted by the double-structured doping device 2 including the outer tube 21 and the inner tube 22 in which the accommodating portion 221 for the volatile dopant is formed in the upper side of the inner tube 22 and the cylindrical portion 222 extends downwardly from the accommodating portion 221 in the above embodiments, the doping device for accommodating the volatile dopant may not necessarily be arranged in the above-described manner but may be of various shapes. In other words, as long as the dopant gas is blown against the semiconductor melt while the crucible is rotated alternately clockwise and counterclockwise, any arrangement may be suitably used for the doping device 2.

In addition, specific structures, procedures and the like in implementing the present invention may be other structures and the like as long as an object of the present invention is achieved.

### EXAMPLES

Next, examples of the present invention will be described. However, the present invention is not limited to the examples.

### [1] Comparison Between Blowing Arrangements

Comparison was made between: an arrangement where the crucible 31 was rotated alternately clockwise and counterclockwise with the rotary speed thereof being changed while the lower distal end of the lateral portion 212 of the outer tube 21 of the doping device 2 was not soaked in the melt in the crucible 31 as shown in FIG. 3 (Example 1); and an arrangement where the crucible 31 was rotated at a constant speed as in a usual doping (Comparative 1). Evaluation was made based on a dopant-absorption index of Example 1, which is calculated with an absorptivity of Comparative 1 being 100 (absorptivity of Example 1/absorptivity of Comparative 1×100).

Doping of both the arrangements was conducted under gas conditions of furnace pressure being 59985 Pa and argon gas flow rate being 200 litters/min.

Doping conditions and experimental results of Example 1 and Comparative 1 are shown in Table 1.

TABLE 1
Enhancement of Absorption Rate by Rotating
Crucible (Blowing Arrangement)

| | | Comparative 1 | Example 1 |
|---|---|---|---|
| Experiment | Crucible Rotary Speed (rpm) | 14FIX | 14 [symbol] −14 |
| Conditions | Change Rate (rpm/min) of | 0 | 1 |
| | Rotary Speed | | |
| | Distal End of Cylindrical | Blowing | Blowing |
| | Portion | | |
| Evaluation | Absorption Index (%) | — | 107.5 |
| | Example/Comparative × 100 | | |

### [2] Comparison Between Soaking Arrangement, Blowing Arrangement and Change Rate of Rotary Speed

Next, comparison was made between: a arrangement where the crucible 31 was rotated alternately clockwise and counterclockwise while the lower end of the lateral portion 212 of the outer tube 21 of the doping device 2 was soaked in the melt; and an arrangement where the crucible was rotated at a constant speed while the lower end of the lateral portion 212 was soaked in the melt.

In Example 2, the rotary speed of the crucible 31 was set to be in a range of −2 rpm to 2 rpm while the change rate of the rotary speed per unit time was set to be 1 rpm/min.

In Example 3, the rotary speed of the crucible was set to be in a range of −20 rpm to 20 rpm while the change rate of the rotary speed per unit time was set to be 5 rpm/min.

In Example 4, the rotary speed of the crucible was set to be in a range of −20 rpm to 20 rpm while the change rate of the rotary speed per unit time was set to be 10 rpm/min.

In Comparatives 2 to 4, experiments were conducted under the same conditions as Comparative 1 except that the dopant amounts and the charge amounts were equalized to those of corresponding Examples.

Doping, conditions and experimental results of Examples 2 to 4 and Comparatives 2 to 4 are shown in Table 2.

TABLE 2
Enhancement of Absorption Rate by Rotating Crucible (Soaking Arrangement)

| | | Comparative 2 | Example 2 | Comparative 3 | Example 3 | Comparative 4 | Example 4 |
|---|---|---|---|---|---|---|---|
| Experimental | Crucible Rotary Speed (rpm) | 14FIX | 2 [symbol] −2 | 14FIX | 20 [symbol] −20 | 14FIX | 20 [symbol] −20 |
| Conditions | Change Rate (rpm/min) of | 0 | 1 | 0 | 5 | 0 | 10 |
| | Rotary Speed | | | | | | |
| | Distal End of Cylindrical | Soaking | Soaking | Soaking | Soaking | Soaking | Soaking |
| | Portion | | | | | | |
| Evaluation | Absorption index (%) | — | 112.2 | — | 115.5 | — | 102.2 |
| | Example/Comparative × 100 | | | | | | |

### [3] Consideration

Comparing Example 1 with Comparative 1, the absorption index of Example 1 is 107.5%, and the dopant absorptivity of Example 1 is more enhanced than that of Comparative 1 in which the rotation was performed at a constant speed. It has been observed that the diffusion of the dopant in the melt is promoted by alternately rotating.

Comparing Examples 2 to 4 with Comparative Examples 2 to 4, in each of which doping was conducted by soaking, the absorption indexes are much more enhanced than in the blowing arrangement. It has been observed that the dopant absorptivity of the melt is increasingly improved by soaking the conduit of the dopant device for guiding the dopant gas in the melt and by alternately rotating the crucible.

However, as shown in Example 4, when the change rate of the rotary speed per unit time is 10 rpm/min, the absorptivity is decreased to be lower than that of Example 3. The absorptivity is decreased presumably because the melt in the crucible could not catch up with the excessively-high increasing rate of the rotary speed of the crucible and could not favorably generate convection changes.

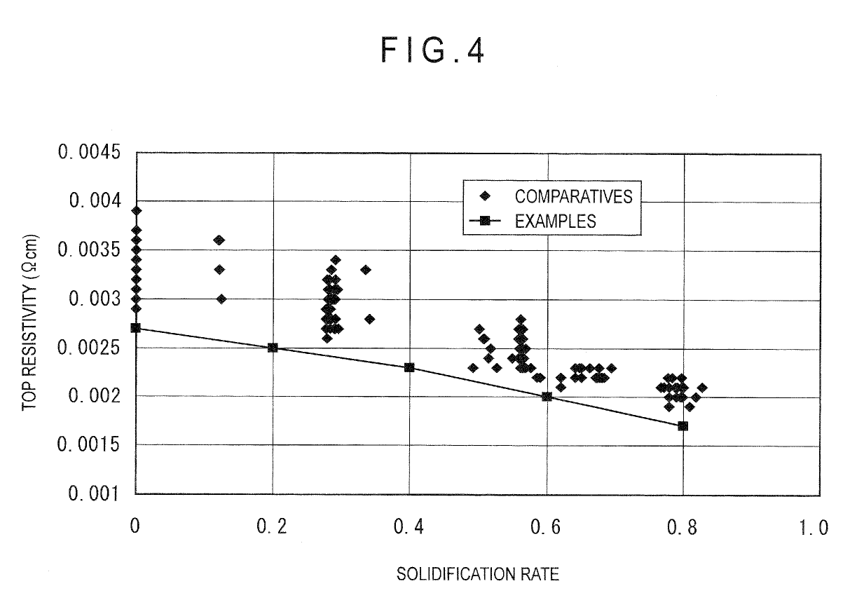

Resistivity measurement was conducted by four probe method on cylindrical body portions of ingots manufactured by alternately rotating the crucible in the soaking arrangement according to Examples and ingots manufactured by rotating the crucible at a constant speed in the blowing arrangement according to Comparatives. As shown in FIG. 4, the cylindrical body portions of the ingots according to Examples exhibited lower resistivity than those according to Comparatives at every point. In other words, it was observed that the dopant was more effectively doped with the melt in Examples.

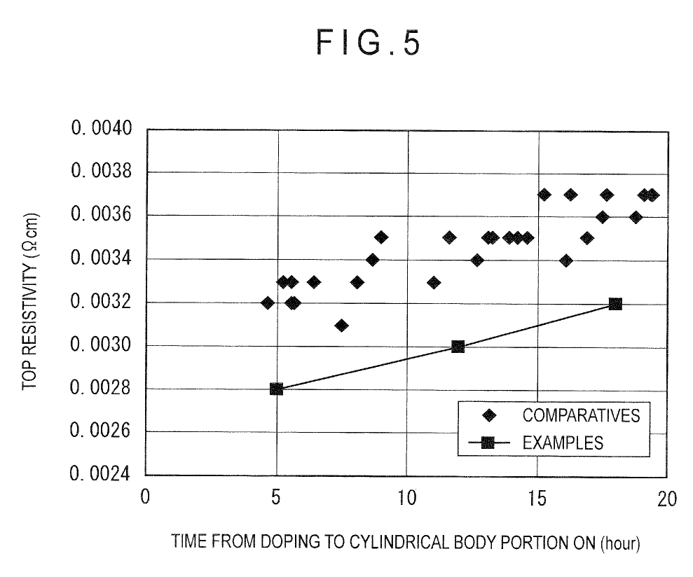

As shown in FIG. 5, observing a relationship between time from the termination of doping to the start of pulling-up of the ingots and resistivity of top portions, it was found that the resistivity of the top portions was not greatly increased even when the time from the termination of doping to the start of pulling-up was long according to Examples.

In other words it was observed that the dopant was effectively injected into the melt in Examples.

### INDUSTRIAL APPLICABILITY

The present invention is applicable to a dopant-injecting method for injecting volatilized dopant gas into semiconductor melt in a crucible.

1. A dopant-injecting method for injecting volatilized dopant gas into semiconductor melt in a crucible, comprising:
rotating the crucible alternately clockwise and counterclockwise around an axis extending in a flowing direction of the dopant gas; and
blowing the dopant gas against the semiconductor melt while rotating the crucible.

2. The method for injecting dopant gas according to claim 1, wherein
the dopant gas is supplied by volatile dopant accommodated in a doping device that comprises a container whose lower end is provided with a conduit for guiding the dopant gas to the semiconductor melt, and
the dopant gas is blown against the semiconductor melt from a distal end of the conduit.

3. The method for injecting dopant gas according to claim 1, wherein a change rate of a rotary speed (rotation number) of the crucible per unit time is in a range of 1 rpm/min to 10 rpm/min.

4. The method for injecting dopant gas according to claim 2, wherein a change rate of a rotary speed (rotation number) of the crucible per unit time is in a range of 1 rpm/min to 10 rpm/min.
